(19) United States
(12) Patent Application Publication
(10) Pub. No.: US 2026/0353857 A1
(43) Pub. Date: Nov. 5, 2026

(54) A LIGHT CONCENTRATING DEVICE FOR TRANSMITTING CONCENTRATED LIGHT TO PHOTOVOLTAIC CELLS, MEANS AND METHODS THEREOF

(71) Applicant: R.P.R ENERGY LTD, Holon (IL)

(72) Inventor: Reuven SHKALIM, Holon (IL)

(21) Appl. No.: 19/119,879

(22) PCT Filed: Oct. 10, 2023
(86) PCT No.: PCT/IL2023/051068

§ 371 Date: Apr. 10, 2025

(30) Foreign Application Priority Data
Oct. 13, 2022 (IL) 297320

(51) Int. Cl. H10F 77/42

(52) U.S. Cl. CPC H10F 77/484

(57) ABSTRACT

A light-concentrating device for transmitting concentrated light to solar modules comprising: (a) a light-receiving portion paved with light-concentrating lenses; (b) an outlet portion for transmitting concentrated light to the solar modules; (c) a nested array of total internally reflecting optical waveguides interposed between the light receiving portion and the outlet portion for propagating the received light between the receiving portion and the outlet portion. Each of the pipes—of the nested array has a hollow cladding accommodating a gas medium therewithin. The cladding has a highly reflective coating thereon. The light-concentrating lenses comprise an optical element having convex and plane-refracting surfaces. The plane refracting surface is tilted to an optical axis of the convex surface such that the solar light is spectrally split into a stretched light pattern, which falls on an array of photovoltaic cells having photosensitivity of a locally incident portion of the stretched light pattern.

### FIELD OF THE INVENTION

The present invention is directed towards the field of concentrator photovoltaics, more specifically, improved arrangements for capturing light and transmitting it efficiently to solar modules and photovoltaic cells.

### BACKGROUND

Concentrator photovoltaics (CPV) (also known as concentration photovoltaics) is a photovoltaic technology that generates electricity from sunlight. Unlike conventional photovoltaic systems, it uses lenses or curved mirrors to focus sunlight onto small, highly efficient, multi-junction (MJ) solar cells. In addition, CPV systems often use solar trackers and sometimes a cooling system to further increase their efficiency.

A major aim of concentrator voltaic technology is to provide high efficiency transfer of light to solar modules or photovoltaic cells in order to develop efficient solar cell modules to make them competitive over conventional power generating means.

The following are examples of recent developments in the field.

U.S. Pat. No. 6,730,840B2, Concentrating photovoltaic module and concentrating photovoltaic power generating system (CANON KABUSHIKI KAISHA). In this publication there is disclosed a concentrating photovoltaic module comprising: a lightguide member having at least one exit face and a plurality of entrance faces; and at least one solar cell placed immediately after the exit face of the lightguide member; wherein the lightguide member is comprised of a light transmissive, solid medium having no refractive-index-discontinuity portion and a surface of the lightguide member is smooth and wherein the lightguide member makes sunbeams incident on the plurality of entrance faces, totally reflected on side faces, and emergent from the exit face, whereby the sunbeams can be concentrated on the solar cell with high efficiency.

U.S. Pat. No. 10,788,180B2 discloses:

An optical device and systems using an optical device are provided, where the optical device may be configured for collimating incoming light rays. The optical device may include a host medium substantially comprised of a transparent material and an array of substantially transparent structures embedded within the host medium. The structures of the array each include a convex side presented to the incoming light rays and a concave side that passes light rays through toward the output face of the host medium, collimating the rays. Multiple stages of arrays may be provided in the optical device, typically with lengthening aspect ratios and increasing indexes of refraction in a direction from the input face toward the output face. The systems may use the optical device for using an exterior light to illuminate an interior space in a building or to generate power.

U.S. Pat. No. 6,541,694B2 discloses:

A non-imaging light concentrator system including a primary collector of light, an optical mixer disposed near the focal zone for collecting light from the primary collector, the optical mixer having a transparent entrance aperture, an internally reflective housing for substantially total internal reflection of light, a transparent exit aperture and an array of photovoltaic cells disposed near the transparent exit aperture.

It remains therefore a long felt and unmet need to improve the efficiency of light concentrators to delivery light energy to solar modules or photovoltaic cells as a useful alternative to conventional means for generating electricity.

### SUMMARY

An object of the present invention is to provide a light concentrating device for transmitting concentrated light to solar modules or photovoltaic cells comprising
a. a light receiving portion paved with light concentrating lenses;
b. an outlet portion for transmitting concentrated light to said solar modules or photovoltaic cells;
c. a nested array of total internally reflecting optical waveguides interposed between said light receiving portion and said outlet portion for propagating said received light between said receiving portion and said outlet portion;
wherein each of said pipes of said nested array has a hollow cladding accommodating a gas medium therewithin said cladding has a highly reflective coating thereon; at least one of the light-concentrating lenses comprising an optical element having convex and plane-refracting surfaces. The convex refracting surface has an optical axis. The optical element is configured for focusing solar light, which is incident onto the convex surface, onto the plane-refracting surface. A normal of the plane refracting surface is tilted to the optical axis of the convex surface such that the focused solar light when refracted outward by the plane refracting surface is spectrally split into a stretched light pattern, which falls on an array of photovoltaic cells having photosensitivity of a locally incident portion of the stretched light pattern.

A further object of the present invention is to provide the gas medium which is air.

A further object of the present invention is to provide the cladding comprising a highly reflective coating of aluminum.

### BRIEF DESCRIPTION OF THE DRAWINGS OF THE PRESENT INVENTION

The novel features believed to be characteristics of the invention are set forth in the appended claims. The invention itself, however, as well as the preferred mode of use, further objects and advantages thereof, will best be understood by reference to the following detailed description of illustrative embodiment when read in conjunction with the accompanying drawings. In order to better understand the invention and its implementation in a practice, a plurality of embodiments will now be described, by way of non-limiting example only, with reference to the accompanying drawings, in which

FIGS. 1-7 are schematic diagrams of embodiments of the present invention.

### DETAILED DESCRIPTION OF THE PRESENT INVENTION

### Photovoltaic Modules

A solar PV module or solar module consists of many PV cells wired in parallel to increase current and in series to produce a higher voltage. The module is often encapsulated with tempered glass (or some other transparent material) on the front surface, and with a protective and waterproof material on the back surface. The edges are sealed for weatherproofing, and there is often an aluminum frame holding everything together in a mountable unit. In the back of the module there is a junction box, or wire leads, providing electrical connections. A solar cell panel, solar electric panel, photo-voltaic (PV) module or solar panel is an assembly of photovoltaic cells mounted in a framework for generating energy. Solar panels use sunlight as a source of energy to generate direct current electricity. A collection of PV modules is called a PV panel, and a system of PV panels is called an array. Arrays of a photovoltaic system supply solar electricity to electrical equipment.

Definitions: terms used in the description of the present invention:

### Refractive Index

The refractive index is a way of measuring the speed of light in a material. Light travels fastest in a vacuum, such as in outer space. The speed of light in a vacuum is about 300,000 kilometers (186,000 miles) per second. The refractive index of a medium is calculated by dividing the speed of light in a vacuum by the speed of light in that medium. The refractive index of a vacuum is therefore 1.

### Total Internal Reflection

When light traveling in an optically dense medium hits a boundary at a steep angle (larger than the critical angle for the boundary), the light is completely reflected. This is called total internal reflection. This effect is used in optical fibers to confine light in the core. Most modern optical fiber is weakly guiding, meaning that the difference in refractive index between the core and the cladding is very small (typically less than 1%). Light travels through the fiber core, bouncing back and forth off the boundary between the core and cladding.

Because the light must strike the boundary with an angle greater than the critical angle, only light that enters the fiber within a certain range of angles can travel down the fiber without leaking out. This range of angles is called the acceptance cone of the fiber. There is a maximum angle from the fiber axis at which light may enter the fiber so that it will propagate, or travel, in the core of the fiber. The sine of this maximum angle is the numerical aperture (NA) of the fiber. Fiber with a larger NA requires less precision to splice and work with than fiber with a smaller NA. The size of this acceptance cone is a function of the refractive index difference between the fiber's core and cladding. Single-mode fiber has a small NA.

### Concentrating Photovoltaic Modules and Systems

Concentrator Photovoltaic systems and modules focus light onto multijunction solar cells. Performance is intrinsically limited by an inability to capture diffuse illumination due to narrow acceptance angles of the conventional concentrator optics. (PNAS, Kyu Tae Lee et al 113 (51) E8210-E8218 https://doi.org/10.1073/pnas.1617391113)

A conventional concentrating photovoltaic (CPV) module comprises three main units, (i) the light receiving unit, which is usually an arrangement of lenses for receiving light, (ii) an output unit (iii) an arrangement of waveguides (optical fibres), for transferring received light to the solar cell.

### Light Losses

An objective technical problem in the field of concentrator voltaics are the losses of light incurred during the transfer of light through the optical fibre waveguides from the light receiving unit (capturing the incoming sunlight) to the light outlet, which emits the captured concentrated light on to the photovoltaic cell for generating electricity.

When light propagates through an optical fiber used to transfer light, a small percentage of light is lost through different mechanisms. The loss of optical power is measured in terms of decibels per km for attenuation losses.

Attenuation is defined as the ratio of optical power output (Pout) from a fiber of length ‘L’ to the power output (Pin)

$$Attenuation \text{?} = \frac{10}{L} log \frac{P \text{?}}{P \text{?}} dB / Km$$

$$\text{?} \text{indicates text missing or illegible when filed}$$

Since attenuation plays a major role in determining the transmission distance, the following attenuation mechanisms are to be considered in designing an optical fiber.

Absorption: Losses due to light absorption occur due to imperfections of the atomic structure such as missing molecules, (OH—), hydroxyl ions, high density cluster of atoms etc., which absorbs light, so the quality of the core

Scattering: Light Scattering is also a wavelength dependent loss, which occurs inside the fibers. In conventional fibres, glass comprises the fibre core and the disordered structure of glass will make some variations in the refractive index inside the fiber. As a result, if light is passed through the atoms in the fiber, a portion of light is scattered (elastic scattering).this type of scattering is called Raleigh scattering.
Raleigh scattering ss ∂1/λ⁴

Radiative loss occurs in fibers due to bending of finite radius of curvature in optical fibers. The types of bends are
a. Macroscopic bends; and
b. Microscopic bends.

### Macroscopic Bends

If the radius of the core is large compared to fiber diameter, it may cause large-curvature at the position where the fiber cable turns at the corner. At these corners, the light will not satisfy the condition for total internal reflection and hence it escapes out from the fiber causing losses.

### Microscopic Bends

Micro-bends losses are caused due to non-uniformities or micro bends inside the fiber and are due to non-uniform pressures created during the cabling of the fiber or even during the manufacturing itself. This lead to loss of light by leakage through the fiber.

The present invention provides a solution to the light losses incurred in the waveguide described above.

The core of the present invention are embodiments providing a light concentrating device for transmitting concentrated light to solar cells and solar cell modules. The device comprises a light receiving portion paved with light concentrating lenses, an outlet portion for transmitting concentrated light to said photovoltaic cells and a nested array of total internally reflecting optical wave guides interposed between said light receiving portion and said outlet portion for propagating said received light between said receiving portion and said outlet portion. The nested array of optical wave guides has high refractive index hollow cores and low refractive index cladding. Each guide is a light transmitting pipe with a light receiving section connecting by a substantially 90 degree bend for receiving incident light with a longitudinal pipe section culminating in a light outlet end.

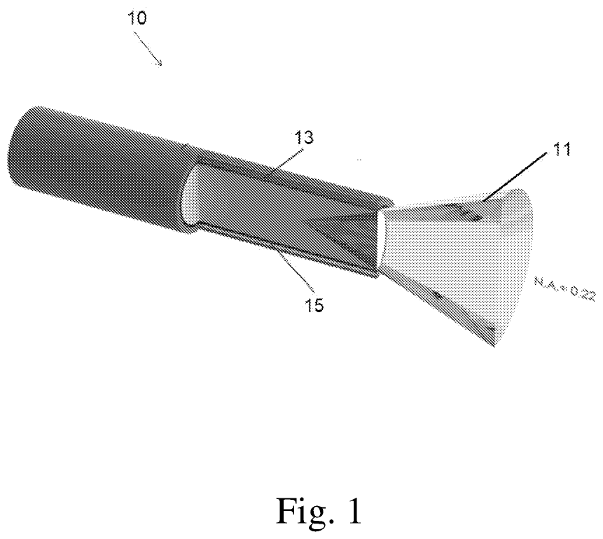

FIG. 1 is a diagram of conventional prior art optical fibre waveguide 10 constituting a cylindrical dielectric waveguide (nonconducting waveguide) that transmits light along its axis through the process of total internal reflection. Fiber 10 consists of a core 15 surrounded by cladding layer 13, both of which are made of dielectric nonconducting materials.

To confine the optical signal in core 15, the refractive index of the core must be greater than that of cladding 13. Core may be glass or silica, and cladding 13 may be glass of a lower refractive index. Because the light must strike the boundary of core 15 and cladding 13 with an angle greater than the critical angle, only light that enters the fiber within a certain range of angles can travel down fiber 10 without leaking out. This range of angles is called the acceptance cone of the fiber. There is maximum angle 11 from the fiber axis at which light may enter the fiber so that it will propagate, or travel, in the core of the fiber. The sine of this maximum angle is the numerical aperture (NA) of the fiber.

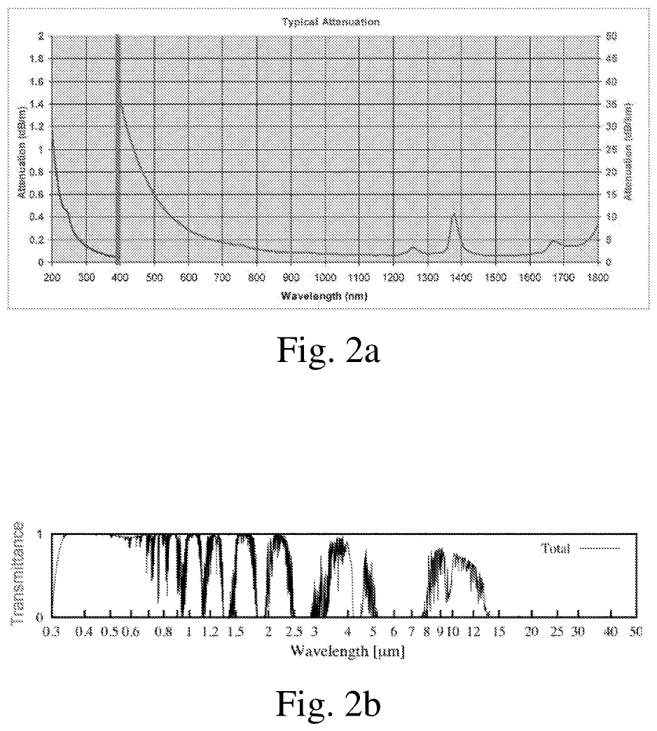

FIG. 2a shows (i) the light losses by attenuation through a conventional light guide with a conventional core.

FIG. 2b shows the light losses by attenuation through a conventional light guide with a gaseous air core of an atmospheric composition measured from ground level referring to about 100 km of air compared to 10-meter need to operate our system.

### Embodiments of the Present Invention

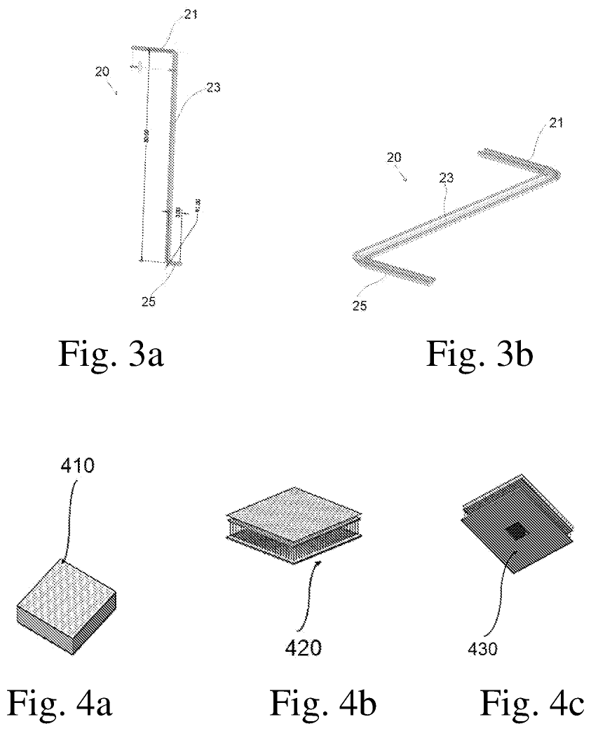

FIGS. 3a and 3b show general and sectional views of individual longitudinal waveguide, which is embodied as a total internally reflecting optical longitudinal aluminum cladding tube, filled with a gas. Light receiving end 21 and light outlet end 25 of waveguide 20 are bent in an approximate 90 degree angle relative to middle portion 23 for receiving incident solar light and directing the solar light to a PV cell (not shown). In some embodiments of the present invention, the cladding pipe is 0.2 mm diameter, and the 90 degree bends have a radius of 0.2 mm.

In general, resultant transmittance of the optical path in the embodiment of the present invention is proportional to the area under the resultant transmittance graph defined by a compound of atmosphere transmittance and optical fibre transmittance. In the prior art case where the optical fibre transmittance is low because of the materials used, the resultant transmittance will be low. In the present invention, the atmospheric transmittance and the optical fibre transmittance will be equal, since both materials are air, and the resultant transmittance will be high.

FIGS. 4a-c show aspects of the device of the present invention. In FIG. 4a, numeral 410 refers to an upper surface paved with planoconvex lenses 4/4/0.5 mm. A further aspect of the device is illustrated in FIG. 4b. The light receiving surface, connected to the upper part of the waveguide array 420 with the waveguide array connected to the light output 430 (FIG. 4c) which conducts the concentrated received light to the PV cell (not shown).

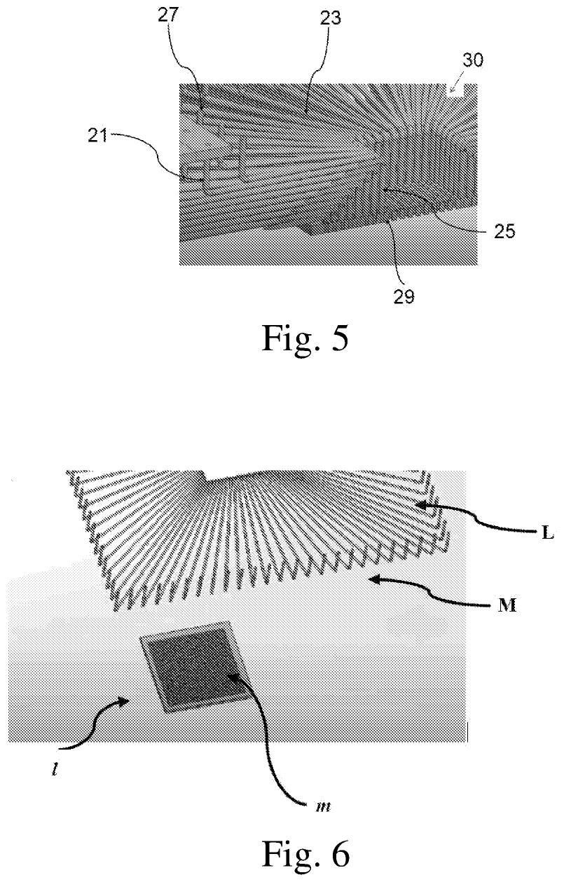

FIG. 5 is an isometric upper cutaway view of an embodiment of the light concentrating device of the present invention. Arrangement 30 is one of several possibilities contemplated in the present invention. As shown FIG. 5, upper light receiving end 21 of the device is paved with concentrator lenses 27, which are arranged in a nested concentric manner, connected to correspondingly nested waveguides. Light received at the aforementioned upper light receiving end 21 of the device propagates through the gas core (passage) within cladding pipe 23 exiting at light outlet end 25 and on to photovoltaic cell 29 to be illuminated.

FIG. 6 illustrates the area A=L×M enclosed by the outer perimeter of the nested array of the light receiving waveguide ends is substantially greater than area a=1×m enclosed by the outer perimeter of the light outlet end.

In this arrangement of the waveguide nested array, efficiency of the use of space and area is optimized, thereby optimizing the quantity of light reaching the solar cell or solar module.

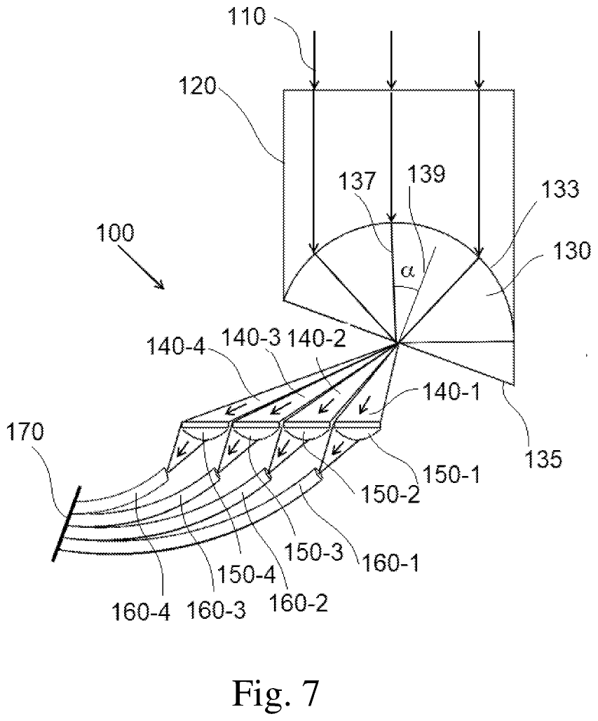

FIG. 7 illustrates light concentrating device 100. Solar light 110 propagates via input optical element 120 is incident onto concave surface 133 of concave-plane optical element 130. The solar light is concentrated on plane surface 135 by refraction on concave surface 133. Normal 139 to plane surface 135 is tilted to optical axis 139 of concave surface 133 at angle q.

The focused solar light when refracted outward by plane refracting surface 135 is spectrally split into a stretched light pattern comprising a number of quasi-monochromatic portions 140-1, 140-2, 140-3 and 140-4. An array of concentrating lenses 150-1, 150-2, 150-3 and 150-4 is configured for directing quasi-monochromatic portions of the stretched light pattern into pipes 160-1, 160-2, 160-3 and 160-4 in a separate manner. Numeral 170 refers to an array of photovoltaic cells having different spectral sensitivity. Pipes 160-1, 160-2, 160-3 and 160-4 are configured for translating said quasi-monochromatic portions responsive to photosensitivity of said photovoltaic cells.

While one or more embodiments of the invention have been described, various alterations, additions, permutations and equivalents thereof are included within the scope of the invention.

In the description of embodiments, reference is made to the accompanying drawings that form a part hereof, which show by way of illustration specific embodiments of the claimed subject matter. It is to be understood that other embodiments may be used and that changes or alterations, such as structural changes, may be made. Such embodiments, changes or alterations are not necessarily departures from the scope with respect to the intended claimed subject matter.

1. A light-concentrating device for transmitting concentrated light to solar modules comprising:
a. a light-receiving portion paved with light-concentrating lenses;
b. an outlet portion for transmitting concentrated light to said solar modules;
c. a nested array of total internally reflecting optical waveguides interposed between said light receiving portion and said outlet portion for propagating said received light between said receiving portion and said outlet portion;
a plurality of said waveguides being a pipe with a light receiving section connecting by a substantially 90-degree bend for receiving incident light with a longitudinal pipe section culminating in a light outlet end, said outlet bend having an approximately 90-degree bend for outputting light;
each of said pipes—of said nested array has a hollow cladding accommodating a gas medium therewithin; said cladding has a highly reflective coating thereon;
wherein at least one of said light-concentrating lenses comprises an optical element having convex and plane refracting surfaces; said convex refracting surface has an optical axis; said optical element is configured for focusing solar light, which is incident onto said convex surface, onto said plane refracting surface; a normal of said plane refracting surface is tilted to said optical axis of said convex surface such that said focused solar light when refracted outward by said plane refracting surface is spectrally split into a stretched light pattern, which falls on an array of photovoltaic cells having photosensitivity of a locally incident portion of said stretched light pattern.

2. The light concentrating device of claim 1, wherein said gas medium is air

3. The light concentrating device of claim 1, wherein said cladding comprises a highly reflective coating of aluminum.
